(19) United States
(12) Patent Application Publication
(10) Pub. No.: US 2024/0360921 A1
(43) Pub. Date: Oct. 31, 2024

(54) AUTO BIT CHECK FOR PNEUMATIC VALVE VERIFICATION

(71) Applicant: Lam Research Corporation, Fremont, CA (US)

(72) Inventors: Rigel Martin Bruening, Sherwood, OR (US); Emile Draper, Molalla, OR (US)

(73) Assignee: Lam Research Corporation, Fremont, CA (US)

(21) Appl. No.: 18/682,020

(22) PCT Filed: Aug. 9, 2022
(86) PCT No.: PCT/US2022/074709

§ 371 Date: Feb. 7, 2024

Related U.S. Application Data
(60) Provisional application No. 63/241,347, filed on Sep. 7, 2021.

(51) Int. Cl. F16K 37/00; H01L 21/67

(52) U.S. Cl. CPC F16K 37/0083; H01L 21/67017

(57) ABSTRACT

An auto bit check feature for pneumatic valve verification as coupled with a gas line that may be coupled with a semiconductor device process chamber. The gas line can be charged to keep a connected valve closed, where activation of a solenoid forces the gas to bleed out and open the valve. The pneumatic gas line may be is purged to keep a connected valve closed, where activation of the solenoid forces gas to flow in the line and apply a pressure to open the valve. One or more airlines may be coupled between solenoid and the valve, depending on the type of solenoid and/or valve. Described is a method to auto verify that a valve is correctly connected to a specific solenoid in a pneumatic bank. The method can enable verification that a particular solenoid opens a desired valve.

### CLAIM FOR PRIORITY

This application is a National Stage Application of and claims the benefit of priority to PCT Patent Application No. PCT/US2022/074709, filed Aug. 9, 2022, which is a non-Provisional of, and claims the benefit of priority to U.S. Provisional Patent Application No. 63/241,347, filed on Sep. 7, 2021, both titled “AUTO BIT CHECK FOR PNEUMATIC VALVE VERIFICATION,” and which are incorporated by reference in entirety.

### BACKGROUND

A pneumatically actuated valve operates through action of a coupled solenoid actuator. Typically, an electrical signal is sent to the solenoid actuator and pistons are activated to push air to open or close the valve. However, when a system includes a plurality of solenoids in a bank, it is desirable to connect and program solenoids to minimize errors and hook up times.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a schematic of system including a programmable solenoid bank with an auto bit check feature for pneumatic valve verification, in accordance with an embodiment of the present disclosure.

FIG. 2A illustrates an isometric illustration of a solenoid bank utilized to enable auto bit check feature for pneumatic valve verification.

FIG. 2B illustrates a cross-sectional illustration of the solenoid bank utilized to enable auto bit check feature for pneumatic valve verification.

FIG. 2C illustrates a plan-view illustration of the solenoid bank utilized to enable auto bit check feature for pneumatic valve verification.

FIG. 3A illustrates a schematic of a flow diagram for a pneumatic bank logic program, in accordance with an embodiment of the present disclosure.

FIG. 3B illustrates a schematic at operation where a computer sends a signal to a pneumatic bank for a desired solenoid actuator to be actuated.

FIG. 3C illustrates a schematic at an operation where the signal reaches the solenoid bank.

FIG. 3D illustrates a schematic at an operation where one of the solenoid actuators is actuated, pressurizing a pneumatic gas line.

FIG. 3E illustrates a schematic at an operation where a pressure sensor measures a pressure in the pneumatic gas line.

FIG. 3F illustrates a schematic at an operation where a computer receives measurement signal from the pressure sensor.

FIG. 3G illustrates a schematic at operation at an operation where there is no change in pressure in the pressure sensor as compared to a reference pressure.

FIG. 4A illustrates a schematic of a flow diagram for method to implement a rate of rise logic program to enable auto bit check for pneumatic valve verification, in accordance with an embodiment of the present disclosure.

FIG. 4B illustrates a schematic at an operation where a process gas supply provides process gas to a first pneumatic valve.

FIG. 4C illustrates a schematic at an operation where the method continues by opening all but a single pneumatic valve to be checked for connectivity.

FIG. 4D illustrates a schematic at an operation where a reference pressure of a process chamber is measured by pressure gauge and recorded by computer.

FIG. 4E illustrates a schematic at an operation where the single pneumatic valve to be checked for connectivity is opened by activating a corresponding solenoid.

FIG. 4F illustrates a schematic at an operation where a rate of pressure rise in the process chamber is measured by a pressure gauge coupled with the process chamber.

FIG. 4G illustrates a schematic at an operation where a rate of pressure rise in the process chamber in an embodiment, where a pair of solenoid actuators are incorrectly coupled with a respective pneumatic valve.

FIG. 5 illustrates a processor system with machine-readable storage media having instructions that when executed cause the processor to perform logic synthesis, in accordance with various embodiments.

### DETAILED DESCRIPTION

Various embodiments describe an auto bit check feature for pneumatic valve verification as coupled with a gas line that is coupled with a semiconductor device process chamber. Current technology implemented in pneumatically actuated valves includes sending signal to a solenoid that is connected by a gas line (for example, air or some other gas) to a respective valve. The gas line (pneumatic gas lines) may be a flexible tube fashioned from polyethylene. The electric signal actuates a piston in the solenoid to move a constituent gas or air in the pneumatic gas line. In an embodiment, the gas line can be charged to keep a connected valve closed, where activation of the solenoid forces the gas to bleed out and open the valve. In a different embodiment, the pneumatic gas line can be purged to keep a connected valve closed, where activation of the solenoid forces gas to flow in the line and apply a pressure to open the valve. One or more airlines may be coupled between solenoid and the valve, depending on the type of solenoid and/or valve.

A semiconductor process equipment such as an etch or deposition toolset, for example, can include a large number of solenoid valves. For operational certification, solenoids are first connected with valves through respective polyethylene tubes. The connections are validated manually. The process can be time consuming, labor intensive and prone to errors when there are a large number of solenoids in a pneumatic bank.

Some embodiments describe a method to auto verify that a valve is correctly connected to a specific solenoid in a pneumatic bank. The method may enable verification that a particular solenoid opens a desired valve. The auto verify method may be executed in two parts. A first part of the auto verify method may be based on incorporating a pressure sensor in a pneumatic gas line of a solenoid. For instance, in an embodiment, pressure sensors may be incorporated in the pneumatic gas lines of a solenoid. In such an embodiment, a pressure sensor may be incorporated in series with the pneumatic gas line. A pressure sensor may be positioned between an outlet side of a solenoid and an inlet side of a valve. A signal may be sent to the solenoid to activate an opening. The solenoid opens pressurizing the polyethylene tube connected to the solenoid. The pressure in the pneumatic gas line may be monitored by the pressure sensor. If there is enough pressure on the outlet of the desired solenoid to actuate the valve, then a signal may be sent from the pressure sensor back to a tool software. The signal may be checked against an activated solenoid channel. A mis-wiring of the solenoid or of the pneumatic gas line may be checked by monitoring a change in pressure in the pneumatic gas line associated with the desired activated solenoid channel.

A second part of the auto verify method may be implemented in a scenario where solenoid activated valves, described above, are included in a process gas line, in accordance with some embodiments. The process gas line may be coupled with a process chamber of, for example, a plasma etch tool or a deposition tool. Depending on the embodiments, a process gas line can include anywhere from a dozen to two dozen process gases that flow from a gas box to a process chamber. In some embodiments, a process gas line may be coupled by a solenoid actuated valve to enable process gas to flow to the chamber. In exemplary embodiments, one or more process gases flows into the chamber via a single process gas line, but there may be a plurality of valves between the process chamber and a gas supply. In one such embodiment, a desired valve can be verified to be open and correctly connected to the specified solenoid on the pneumatic bank by using a modified version of the Rate of Rise (ROR) program for the tool. This program may operate by measuring an increase in pressure in the chamber after the desired valve is opened. In an embodiment, all valves except the desired valve in the process gas line may be opened. The chamber pressure may be measured prior to and after opening the desired valve to be verified for connectivity. If a change in chamber pressure (for example, increase) is observed then the desired pneumatic valve may be verified as having a proper pneumatic gas line connectivity, in accordance with some embodiments.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

In the following description, numerous specific details are set forth, such as structural schemes and detailed fabrication methods in order to provide a thorough understanding of embodiments of the present disclosure. It will be apparent to one skilled in the art that embodiments of the present disclosure may be practiced without these specific details. In other instances, well-known features, such as process equipment operations, arc described in lesser detail in order to not unnecessarily obscure embodiments of the present disclosure. Furthermore, it is to be understood that the various embodiments shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

As used throughout this description, and in the claims, a list of items joined by the term “at least one of” or “one or more of” can mean any combination of the listed terms.

Unless otherwise specified in the explicit context of their use, the terms “substantially equal,” “about equal” and “approximately equal” mean that there is no more than incidental variation between two things so described. In the art, such variation is typically no more than +/−10% of a predetermined target value.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

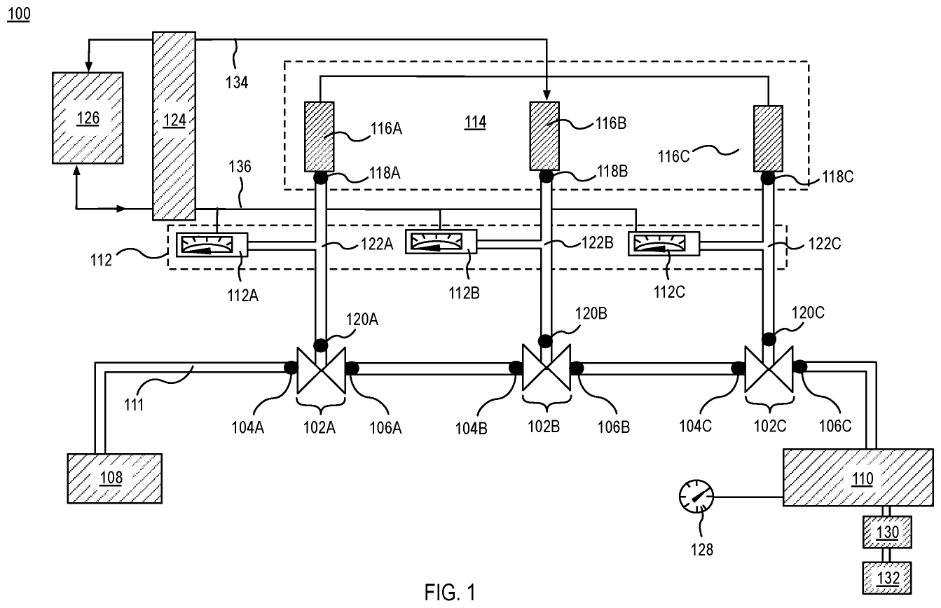

FIG. 1 illustrates a schematic of system 100 including a programmable solenoid bank with an auto bit check feature for pneumatic valve verification, in accordance with some embodiments of the present disclosure. System 100 includes a plurality of pneumatic valves 102 (herein pneumatic valves 102) in series. In the illustrative embodiment, system 100 is an example of a deposition system 100. In other examples, system 100 may be an example of an etch system 100. The number of pneumatic valves 102 in series may be system specific. In the illustrative embodiment, three pneumatic valves are shown. However, any number of valves may be used. Individual pneumatic valves 102A, 102B and 102C may have an inlet and an outlet. Individual pneumatic valves 102A, 102B and 102C may have an inlet 104A, 104B and 104C, respectively and an outlet 106A, 106B and 106C, respectively. As shown, inlet 104A can be coupled to a process gas supply 108, and an outlet 106C of a last of pneumatic valves 102 can be connected to the process chamber 110. A process gas line 111 couples gas supply 108 with pneumatic valves 102 and process chamber 110. Process gas supply 108 may include anywhere from 2-24 process gases, for example. One process gas line 111 is shown for illustration purposes only. The number of process gas lines 111 may also vary depending on system 100 and application.

System 100 further includes a plurality of pressure sensors 112 (herein pressure sensors 112) and a pneumatic bank 114. Pneumatic bank 114 includes a plurality of solenoid actuators 116A, 116B and 116C (herein solenoid actuators 116A, 116B and/or 116C). In general, the number of solenoid actuators 116A, 116B and 116C and the number of pressure sensors 112 may be equal to the number of pneumatic valves 102. In the illustrative embodiment, individual solenoid actuators 116A, 116B and 116C may be mechanically coupled with individual pneumatic valves 104A, 104B and 104C, respectively. Pressure sensors 112A, 112B and 112C may further be coupled between a respective solenoid actuator 116A, 116B and 116C and the respective pneumatic valve 102A, 102B and 102C. In some embodiments, pressure sensors 112 may include an absolute pressure sensor, a gauge pressure sensor or a differential pressure sensor. In some embodiments, gauges within pressure sensors 112 may include a resistive, capacitive or an inductive air pressure transducer. In an embodiment, solenoid actuators 116 includes a coil that can generate a magnetic field. The magnetic field generated in response to a current flowing through the coil causes a shaft and a magnetic core that may be movable within the coil to shift. Energy produced by a magnetic field generated by the coil may be used to propel the magnetic core along the length of the shaft. The motion of the shaft opens and closes a pathway between an inlet and an outlet of the solenoid actuator enabling fluid flow to a connected pneumatic gas line.

As shown, pressure sensors 112A, 112B and 112C can be coupled between a pneumatic gas outlet 118A, 118B or 118C of the respective solenoid actuator 116A, 116B or 116C and a pneumatic gas inlet 120A, 120B or 120C of the respective pneumatic valve 104A, 104B or 104C. Pressure sensors 112A, 112B and 112C may be configured to measure a relative change in a reference pneumatic gas pressure within a respective pneumatic gas line 122A, 122B and 122C. Pneumatic gas lines 122A, 122B and 122C can be respectively coupled between pneumatic gas outlet and pneumatic gas inlet pairs such as 118A and 120A, 118B and 120B, and 118C and 120C, as shown.

System 100 further includes a communication interface 124 coupled to pneumatic bank 114 and pressure sensors 112. Communication interface 124 can be configured to carry signal 134 to and from pneumatic bank 114 and signal 136 to and from pressure sensors 112. The signals 134 and 136 can enable control and/or monitor status of an individual valve 102A, 102B or 102C. Communication interface 124 may be controllable by software stored in a computer 126 to send and/or receive one or more signals to and from communication interface 124. Communication interface 124 can be any suitable interface such as Universal Serial Bus (USB) compliant interface, I2C, or any other serial or parallel interface, etc.

Pressure measurements in pneumatic gas lines 122A, 122B and 122C can indicate to computer 126 about accurate wiring of solenoid actuator 116A, 116B and 116C. Additionally, pressure measurements in pressure sensors 112A, 112B and 112C and in process chamber 110 can enable computer software to validate accurate connectivity between solenoid actuator 116A, 116B and 116C and respective pneumatic valve 102A, 102B and 102C.

Process chamber 110 includes a chamber pressure measurement gauge 128 and a throttle valve 130 coupled between a vacuum pump 132 and process chamber 110. The process chamber 110 may be utilized for etch, deposition, vapor cleaning or plasma ashing processes. In some embodiments, the chamber pressure gauge may include a convectron gauge or an ionization gauge depending on the chamber pressure range desired. A convectron gauge employs a principle of a Wheatstone bridge to convert chamber pressure to voltage. The ionization gauge works by ionizing gas molecules within a volume of the ionization gauge. The gas molecules are introduced from the chamber into a volume of the ionization gauge by an opening in a body of the ionization gauge. Ions produced by the ionization can be collected on a thin wire, called a collector. A current measured in the thin wire can be proportional to pressure in the chamber.

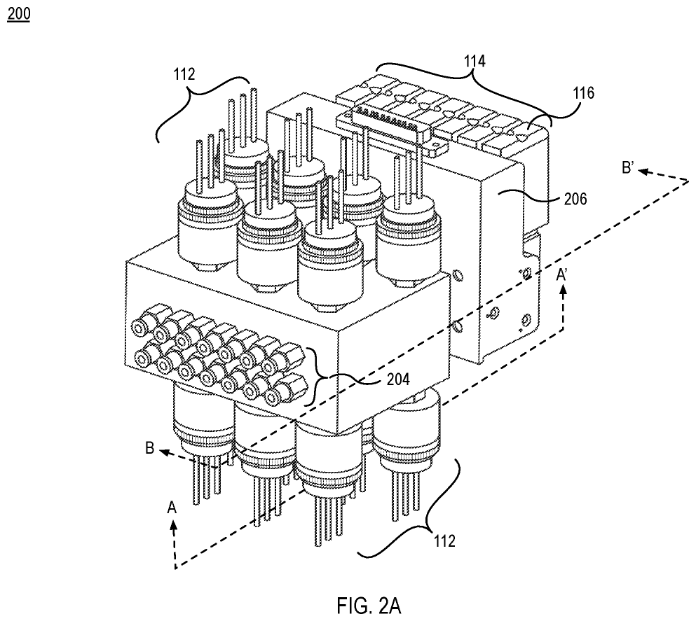

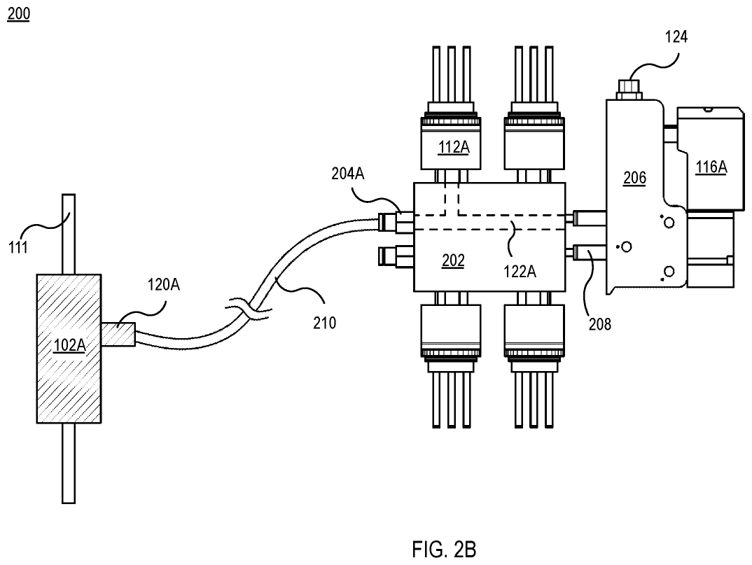

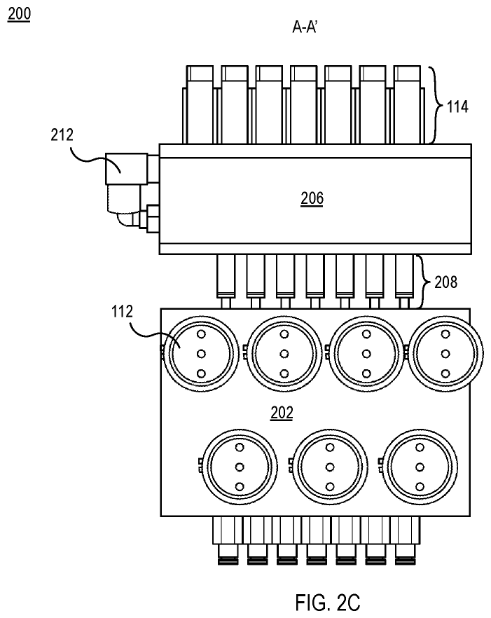

FIG. 2A is an isometric illustration of apparatus 200, in accordance with some embodiments. Apparatus 200 includes components of system 100 illustrated in FIG. 1. As shown, apparatus 200 includes pressure sensors 112 and pneumatic bank 114 including a plurality of solenoid actuators 116. In the illustrative embodiment, seven solenoid actuators 116 are shown. However, any number of solenoid actuators 116 can be used. For example, the number of solenoid actuators 116 can range between 2-20. In an embodiment, solenoid actuators 116 can be a direct-acting valve, a pilot operated valve or two-way valves. Valves within the solenoid may provide pathway for pneumatic gas to flow and can be distinct from the pneumatic valves 102 that are coupled with a respective solenoid actuator 116A, B or C. In some embodiments, the number of valves can be at least two. In some embodiments, the number of valves can be at least two but less than 20.

As shown, pressure sensors 112 may be mounted on housing 202. Pressure sensors 112 may have a lateral width, Ls, that is between 2 cm and 4 cm. In the illustrative embodiment, housing 202 can be a box and pressure sensors 112 can be mounted on a top surface and on a bottom surface of the metal box. The material for the box can be any suitable material, such as metal. Or rigid plexiglass, that can provide physical support for the pressure sensors, pneumatic gas lines and coupling for the solenoid bank and communication interface 124. Housing 202 includes pneumatic gas connectors 204. A flexible polyethylene tube may be coupled between pneumatic gas connector 204A, 204B etc. and a respective valve (such as valve 102A in FIG. 1).

In an embodiment, apparatus 200 further includes housing 206 for communication interface 124. Communication signals can be sent to and from computer 126 to pneumatic bank 114 or to the plurality of pressure sensors 112 via communication interface 124 by one or more connector cables (omitted for clarity). In a different embodiment, a wireless receiver and/or transmitter can be connected with communication interface 124 to perform wireless communication to and from computer 126. In both embodiments, the communication signals may be used to control solenoid actuators 116 (to control valves coupled with a respective solenoid actuator 116) and monitor readings from pressure sensors 112. The communication signals may be controllable by a software. In the illustrative embodiment, communication interface 124 includes a standard density connector.

In some embodiments, one or more circuit boards and electrical components that can be connected with the communication interface 124 may be located inside housing 206. Depending on the number and size of pressure sensors 112, housing 206 may have a length between 5 cm and 10 cm and a width between approximately 2 cm and 4 cm.

FIG. 2B is a side view illustration of apparatus 200 taken along the line B-B′ in FIG. 2A, in accordance with some embodiments. In the illustrative embodiment, solenoid actuators 116 can be coupled with housing 206. Apparatus 200 further includes manifold connectors 208 between housing 206 and housing 202. In the cross-sectional illustration, two manifold connectors 208 are shown. Manifold connectors 208 can be designed to provide mechanical stability for coupling between housing 202 and housing 206. A plurality of pneumatic gas line can extend between solenoid actuator 116 and pneumatic gas connectors 204. As shown pneumatic gas line 122A can extend between gas connector 204A and solenoid actuator 116A. In an exemplary embodiment, pressure sensor 112A may be coupled with a section of the pneumatic gas line 122A. The pneumatic gas line 122A can extend through manifold connector 208A to solenoid actuator 116A through housing 206. Pressure sensor 112A can monitor pressure in pneumatic gas line 122A.

Pneumatic gas line 122A can further extend from pneumatic gas connector 204A to a corresponding pneumatic valve. In the illustrative embodiment, pneumatic gas line 122A can further include a section 210 between pneumatic gas connector 204A and pneumatic gas inlet 120A of pneumatic valve 102A. Pressure sensor 112A can monitor pressure in pneumatic gas line 122A and section 210.

FIG. 2C illustrates a plan view of apparatus 200 taken along the line A-A′, in accordance with some embodiments. Housing 206 can include a high-pressure inlet 212 to solenoid bank 114. The plan view illustrates connectivity between housing 202 where pressure sensors 112 can be located and the housing 206 can be coupled with solenoid bank 114.

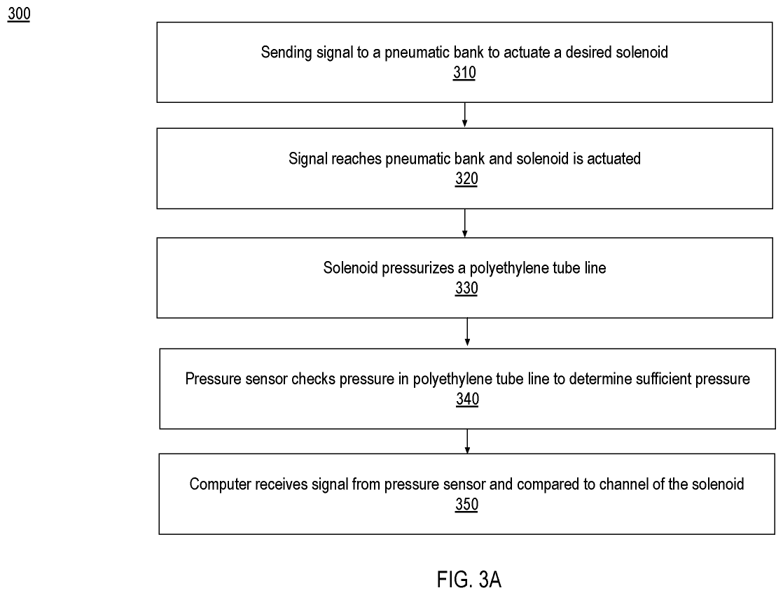

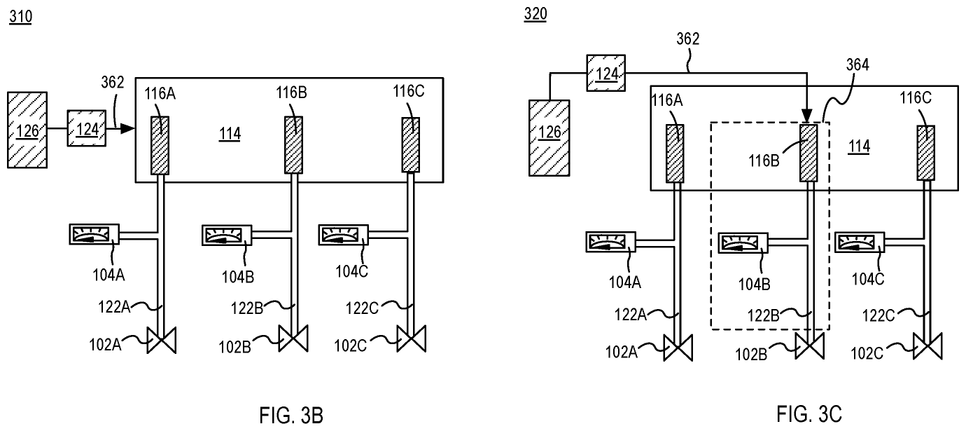

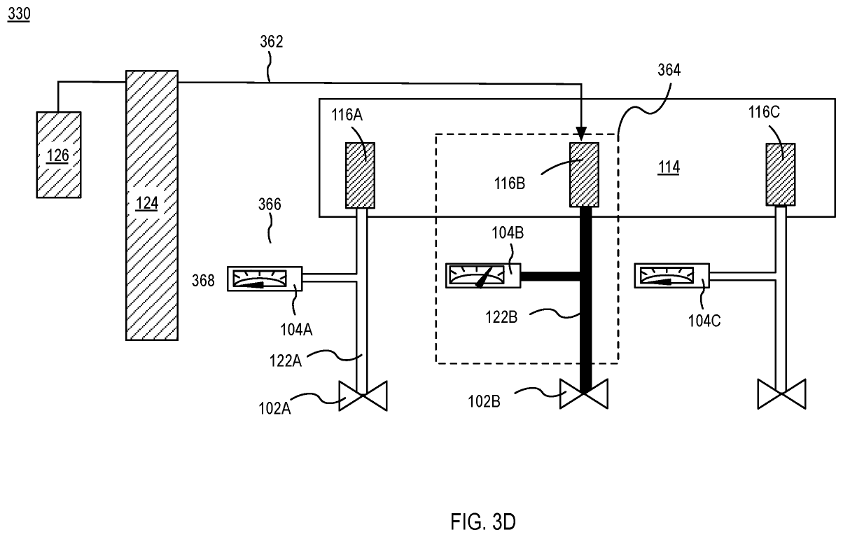

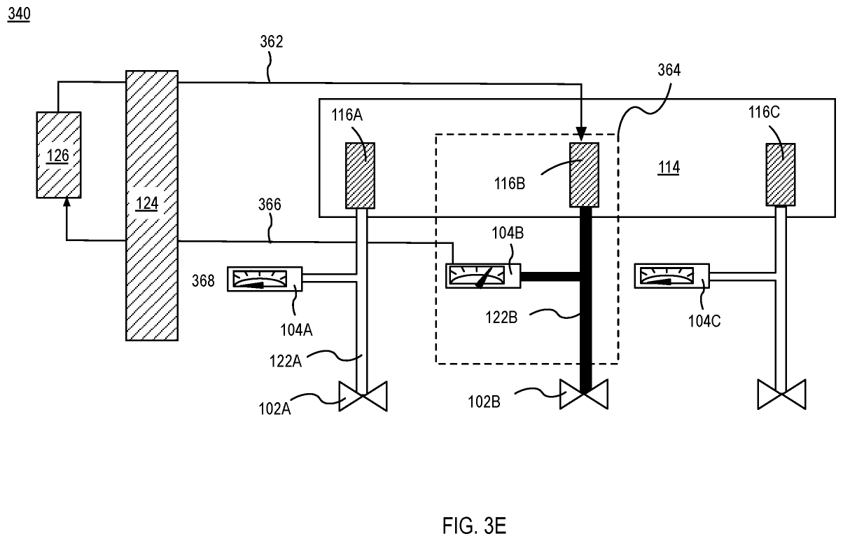

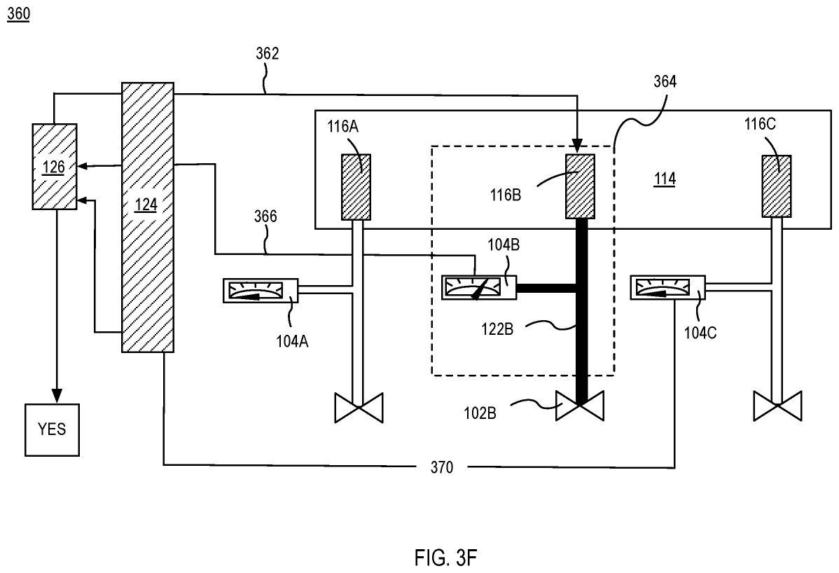

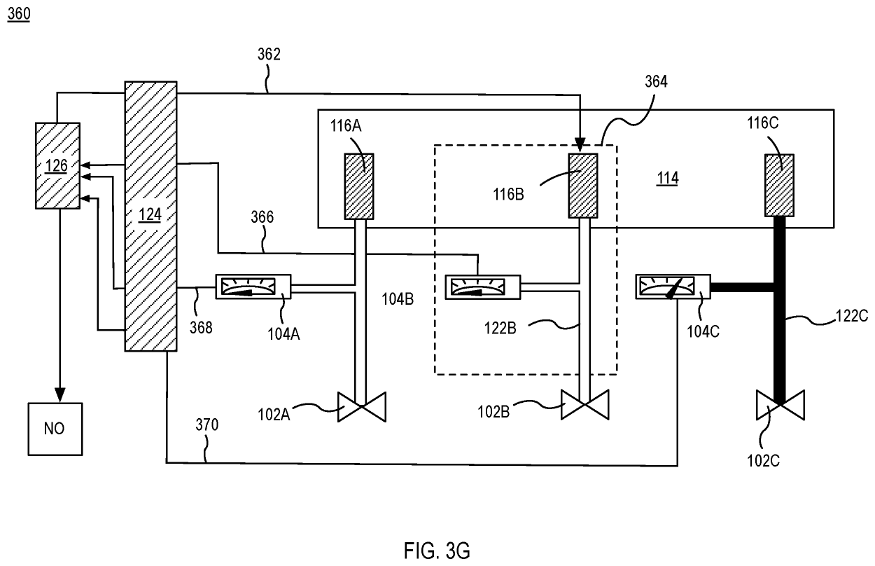

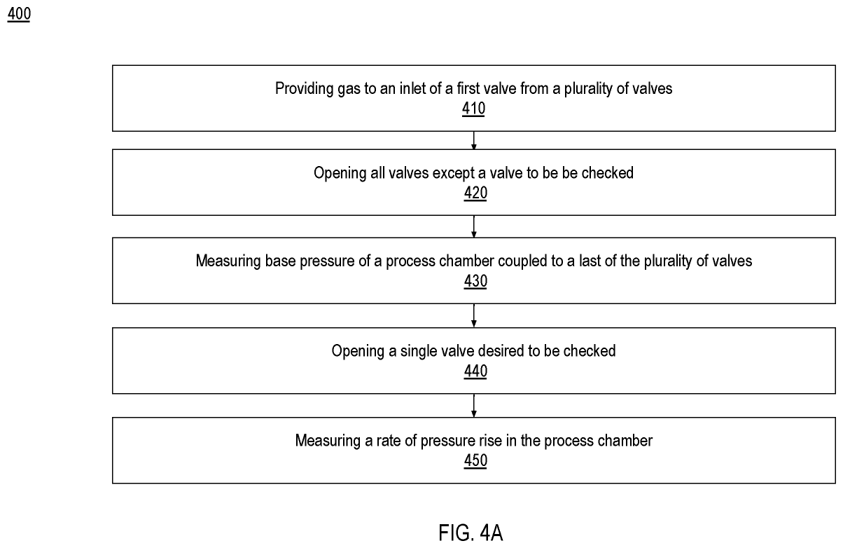

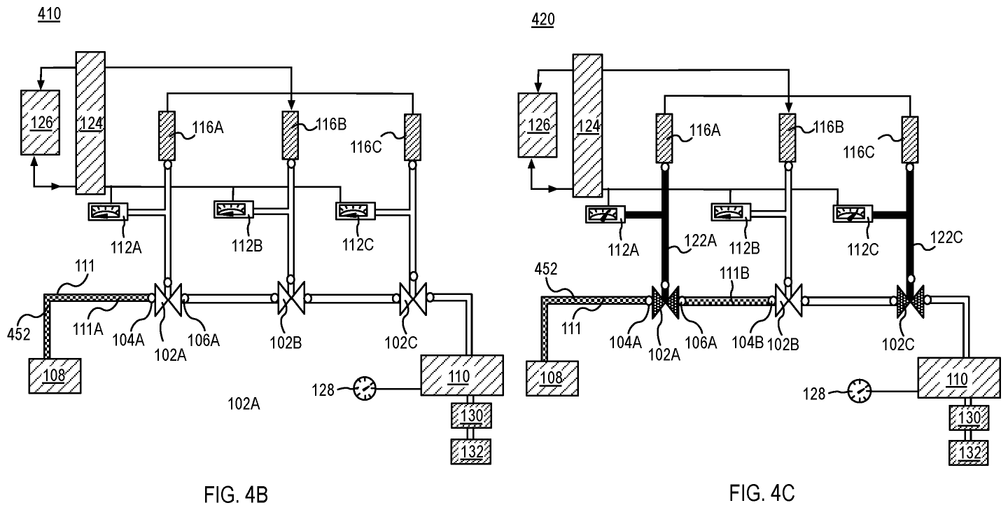

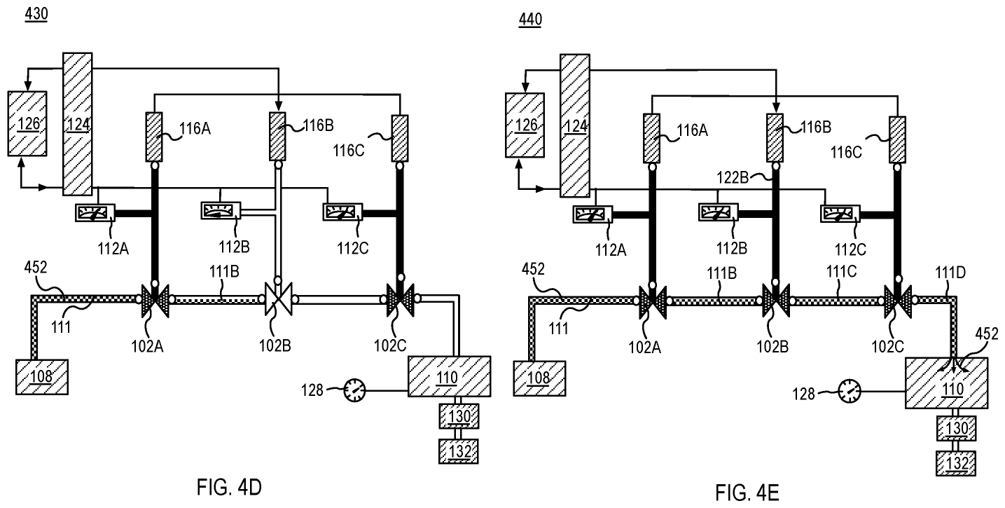

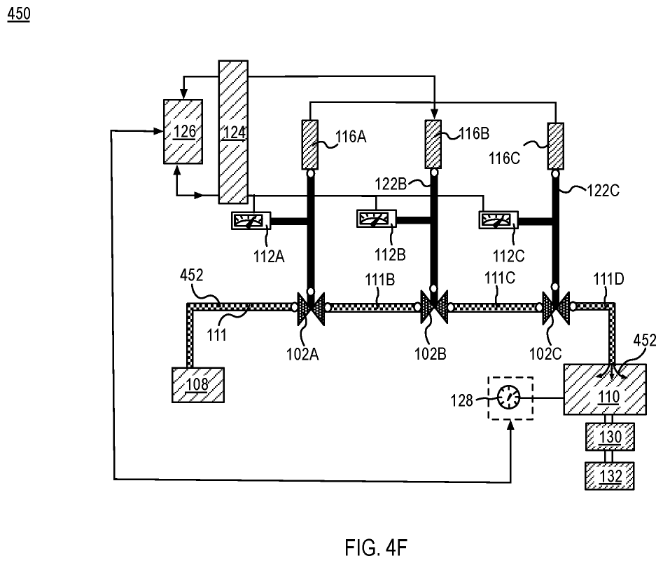

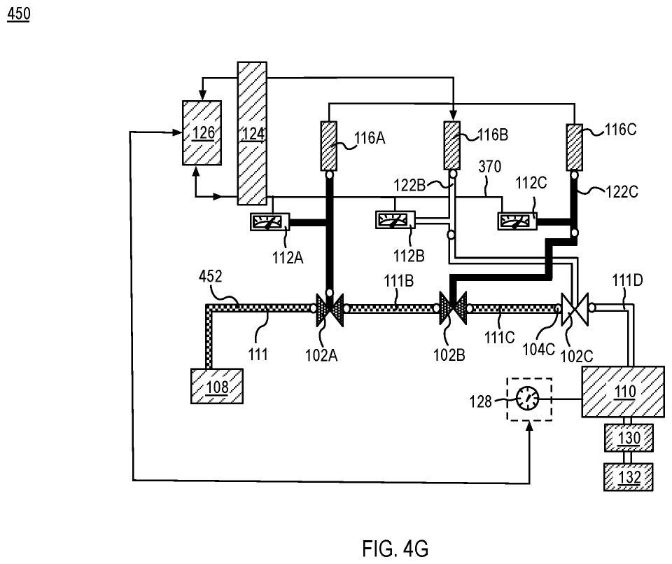

Referring again to FIG. 1, pneumatic gas lines 122A, 122B and 122C can be validated to be coupled with a correct corresponding pneumatic valve by an auto bit check procedure. The procedure may be carried out in two parts. A first part includes a flow chart depicted in FIG. 3A and a second part includes a flow chart depicted in FIG. 4A.

FIG. 3A illustrates a flow diagram of method 300 implemented to verify a correct solenoid to pneumatic gas line connectivity, where method 300 includes performing the following operations. While various operations of method 300 are shown in a particular order, the order can be modified. For example, some operations may be performed before others while some operations may be performed in parallel. The operations herein can be performed or controlled by hardware, software, or a combination of them.

Method 300 begins at operation 310 by sending a signal to a pneumatic bank to actuate a desired solenoid, where the signal is sent by a computer. Method 300 can continue at operation 320 where the signal reaches the pneumatic bank, and the desired solenoid may be actuated. Method 300 continues at operation 330 where the solenoid pressurizes a line, for example, a polyethylene tube line connected to a pneumatically actuated valve. Method 300 continues at operation 340 where a pressure sensor in series with polyethylene tube line checks if pressure in the polyethylene tube line is sufficient. Method 300 can conclude at operation 350 where the computer receives signal from the sensor and the signal received from the sensor is compared against a known channel of solenoid activated.

FIGS. 3B-3F illustrate an implementation of method 300 (described in association with FIG. 3A) in system 100.

FIG. 3B illustrates a schematic at operation 310. Computer 126 can send a signal 362 to a pneumatic bank 114 for a desired solenoid actuator 116A, 116B or 116C to be actuated. Only one of the solenoids 102A, 102B or 102C may be actuated and checked at a time. In an embodiment, all valves 102A, 102B and 102C can be normally closed. In some such embodiments, pneumatic gas lines 122A, 122B and 122C may not be charged.

FIG. 3C illustrates a schematic at operation 320. At operation 320, signal 362 reaches solenoid bank 114 and a desired solenoid can be actuated. In the illustrative embodiment, solenoid 102B can be chosen to be actuated as indicated by dashed box 364.

FIG. 3D illustrates a schematic at operation 330. At operation 330, solenoid 116B can be actuated and can pressurize pneumatic gas line 122B. In an embodiment, pneumatic gas line 122B can be a polyethylene tube line that is pressurized or charged with air. The pneumatic gas line 122B may be pressurized with air to a gauge pressure between 60 and 120 PSI.

FIG. 3E illustrates a schematic at operation 340. At operation 340 pressure sensor 104B measures a pressure in pneumatic gas line 122B. As shown 340 pressure sensor 104B can be in series with pneumatic gas line 122B between solenoid 116B and valve 102B. Pressure sensor 104B can send a measurement signal 366 to computer 126. The measurement may provide a check that there is sufficient pressure in pneumatic gas line 122B (or on an outlet of the desired solenoid 116B).

FIG. 3F illustrates a schematic at operation 350. At operation 350, computer 126 may receive measurement signal 366 from pressure sensor 104B. Measurement signal 366 can provide one of two indications. In one embodiment, there can be a change in pressure sensed in pressure sensor 104B compared to a reference pressure. The reference pressure is measured before actuating solenoid 116B. If there is a pressure change, measurement signal 366 can also indicate if there is sufficient pressure on the outlet of the desired solenoid 116B to actuate pneumatically actuated valve 102B.

If a change in pressure is sensed in pressure sensor 104B then a comparison with a solenoid that is desired to be activated can be performed by the computer 126. If the desired solenoid 116B brings about a change in the pressure in pressure sensor 104B then the result is affirmative and pneumatic gas line 122B can be verified to be a correctly connected to solenoid 116B.

In a second embodiment there is no change in pressure in the pressure sensor 104B as compared to a reference pressure. FIG. 3G is a schematic at operation 350 where there is no change in pressure in the pressure sensor 104B as compared to a reference pressure. In one embodiment, signal 362 activates solenoid 116C even though 116B may be the solenoid that is desired to be opened. In one such embodiment, pneumatic gas line 122C can be pressured as indicated (shaded). Pressure sensor 104B can send computer 126 a signal 366, where signal 366 can specify that there is no measured increase in pressure compared to a reference pressure. The computer 126 can subsequently check all remaining pressure sensors 104A and 104C to see if there are any false positives. A false positive reading can be rendered when a pressure sensor other than a desired pressure sensor reports a change in pressure in a corresponding pneumatic gas line. In some embodiments, the desired pressure sensor can send a notification to a computer. The notification can be indicative of opening of the single valve to change the reference pressure. In the illustrative embodiment, signals 366 and 368 may not render a measurement that indicates a change in pressure in respective pneumatic gas line 122B and 122A. However, as shown, signal 370 from pressure sensor 104C can render a measurement specifying an increase in pressure in pneumatic gas line 122C. When compared against desired solenoid 116B, a change in pressure in pneumatic gas line 122C can indicate that the result is negative and pneumatic gas line 122B may not be verified to be a correctly connected to solenoid 116B.

In a different embodiment, pressure changes in pressure sensors 104B, 104A or 104C can be measured through signals 366, 368 or 370, respectively. In some such embodiment, checks of signal cable integrity, malfunctioning solenoids or inadequate pneumatic gas supply pressure can be manually performed.

Method outlined in FIGS. 3A-3G can provide validation if a desired solenoid is connected to a desired pneumatic gas line. However, further validation of a desired solenoid with a desired pneumatic valve (through a correctly connected pneumatic gas line) may be depended on a further test. In accordance with embodiments of the present disclosure, the test includes actuation of pneumatic valves and measurement of pressure changes in a process chamber. as described below.

FIG. 4A illustrates a flow diagram of method 400 to verify a valve function, where the method 400 includes performing the following operations. Method 400 begins at operation 410 by providing a gas to an inlet of a first valve from among a plurality of valves. Method 400 may continue at operation 420 by opening all valves except a single valve to be checked. Method 400 may continue at operation 430 by measuring a reference pressure of a process chamber coupled with a last of the plurality of valves. Method 400 may continue at operation 440 by opening the single valve by energizing the respective solenoid actuator coupled to the single valve. Method 400 concludes at operation 450 by measuring a rate of pressure rise in the process chamber by a vacuum gauge coupled with the process chamber. A presence or a lack of pressure rise may be indicative of whether the right valve is activated.

FIG. 4B illustrates a schematic at operation 410. At operation 410, process gas supply 108 may provide process gas 452 to a first pneumatic valve 102A from among a plurality of valves. The pneumatic valve 102A may be closest in proximity along process gas line 111 to the process gas supply 108. In the illustrative embodiment, the pneumatic valves 102A, 102B and 102C can be closed. The process gas can be confined to a section 111A of the gas line up to the inlet 104A of pneumatic valve 102A. In an embodiment, the solenoid actuators 116A, 116B and 116C may be inactive because pneumatic valves 102A, 102B and 102C can be of a normally closed type, as described above. The closure may be in agreement with the operations described above.

FIG. 4C illustrates a schematic at operation 420. At operation 420, method 400 may continue by opening all pneumatic valves but the pneumatic valve to be checked for connectivity. For example, as shown, pneumatic valves 102A and 102C can be opened but pneumatic valve 102B may be left in a closed state. In the illustrative embodiment, pneumatic valve 102B may be checked for connectivity with solenoid actuator 116B. As pneumatic valve 102A is opened, gas 452 travels through pneumatic valve 102A, beyond outlet 106A into process gas line section 111B. However, because pneumatic valve 102B is closed, the process gas 452 stops at inlet 104B. The fact that valve 102C is open, as indicated by pressure sensor 112C, and charged pneumatic gas in pneumatic gas line 122C, has no further consequence on the flow of process gas 452.

FIG. 4D illustrates a schematic at operation 430. At operation 430 a reference pressure of the process chamber 110 can be measured by pressure gauge 128 and recorded by computer 126.

FIG. 4E illustrates a schematic at operation 440. At operation 440, pneumatic valve 102B can be opened by activating solenoid 116B. If the pneumatic gas line 122B is correctly connected to the pneumatic valve 102B, then process gas 452 may flow into section 111C. Furthermore, in the illustrative embodiment, since valve 102C is open, then process gas 452 may also flow into section 111D and in process chamber 110, as shown.

FIG. 4F illustrates a schematic at operation 450. Method 400 may conclude at operation 450 by measuring a rate of pressure rise in the process chamber 110 by a pressure gauge 128 coupled with the process chamber 110. If process gas 452 flows into process chamber 110 after opening pneumatic valve 102B, as illustrated, then pressure in chamber may be expected to rise. A rate of rise in chamber pressure can be measured by the pressure gauge 128. If the rate of rise is non-zero, then opening of pneumatic valve 102B is validated. If opening of pneumatic valve 102B is validated, then connection of pneumatic gas line 122B with pneumatic valve 102B can also be confirmed.

It is to be appreciated that in method 400 described above at least one pneumatic gas line connection may be manually validated for connectivity with a pneumatic valve before the rate of rise program is administered. For example, pneumatic gas line 122A may be manually verified to be connected to pneumatic valve 102A before opening any pneumatic valve 102A, 102B or 102C. In such an example, when solenoid actuator 116C is activated to charge pneumatic gas line 122C, one of the following two actions may occur. In a first action, if pneumatic gas line 122C is validly connected to pneumatic valve 102C, then pneumatic valve 102C may open and pneumatic valve 102C may remain closed. However, no process gas 452 may flow because process gas 452 may not travel beyond inlet 104B. The rate of rise program may provide verification that pneumatic gas line 122B can be validly connected to valve 102B. If, however, pneumatic gas line 102C and 102B are interchanged, the following second action may occur as illustrated in the schematic in FIG. 4G. When solenoid actuator 116C is activated, pressure sensor 112C may indicate that pneumatic gas line pressure 122C is adequate. Signal 370 can be transmitted to computer 126 via communication interface 124 and pneumatic valve 102B will open. Process gas 452 may flow up to inlet 104C, along section 111C, but not beyond valve 102C. When pneumatic actuator 116B is activated valve 102C may open and process gas 452 may flow into section 111D and rate of pressure rise may be measured in process chamber 110.

The validation method may be utilized for any number of valves on gas line 111 coupled between process gas supply 108 and process chamber 110. The validation method stipulates that a valve in closest proximity to the process chamber 110 can be validated first and other valves (such as 102B and 10A) subsequently validated to accurately validate valves 102C, 102B and 102A.

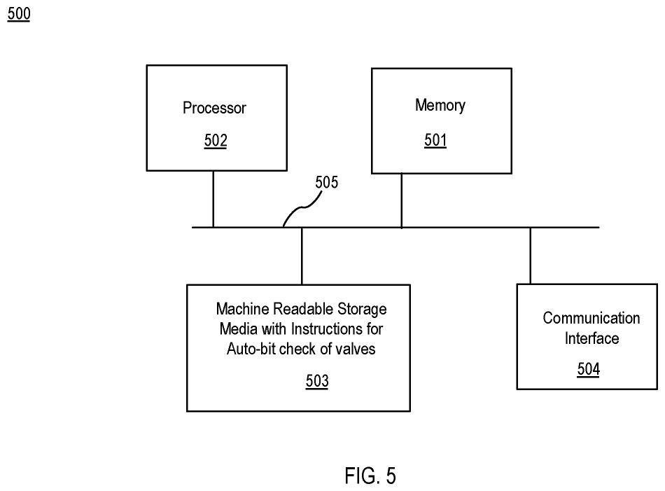

FIG. 5 illustrates processor system 500 with machine-readable storage media having instructions that when executed cause the processor to perform logic synthesis, in accordance with various embodiments. Elements of embodiments (e.g., the flowchart described herein) may also be provided as a machine-readable medium (e.g., memory) for storing the computer-executable instructions (e.g., instructions to implement any other processes discussed herein). In some embodiments, computing platform 500 comprises memory 501, processor 502, machine-readable storage media 503 (also referred to as tangible machine readable medium), communication interface 504 (e.g., wireless or wired interface), and network bus 505 are coupled as shown.

In some embodiments, processor 502 can be a Digital Signal Processor (DSP), an Application Specific Integrated Circuit (ASIC), a general-purpose Central Processing Unit (CPU), or a low power logic implementing a simple finite state machine to perform the method of the various flowcharts, etc.

In some embodiments, the various logic blocks of system 500 may be coupled together via network bus 505. Any suitable protocol may be used to implement network bus 505. In some embodiments, machine-readable storage medium 503 includes instructions (also referred to as the program software code/instructions) for auto bit check feature for pneumatic valve verification as coupled with a gas line. and as described above with reference to various embodiments and flowcharts.

In one example, machine-readable storage media 503 is a machine-readable storage media with instructions for auto-bit check of valves 503 (herein machine readable medium 503). Machine-readable medium 503 has machine-readable instructions, that when executed, cause one or more machines to perform a method. The method includes providing a process gas to an inlet of a first valve from among a plurality of valves, where the plurality of valves can be coupled in series. An outlet of a second valve among the plurality of valves may be connected with a process chamber, where the plurality of valves can be in a closed position. The method further includes opening all but a single valve in the plurality of valves by actuating a respective solenoid actuator coupled with individual ones of the plurality of valves. The respective solenoid actuator is among a plurality of solenoid actuators in a pneumatic bank. The method further includes pumping the process chamber to a reference pressure and opening the single valve by energizing the respective solenoid actuator coupled to the single valve. Opening the single valve can cause the process gas to flow to the process chamber.

In one example, machine-readable instructions that when executed, cause the one or more machines to determine whether the one or more machines received a signal from the pressure sensor. The executed instructions may also indicate that the respective solenoid actuator can be activated if it can be determined that signal is received from the pressure sensor.

In a second example, machine-readable instructions, that when executed, cause the one or more machines to perform a further method of checking remaining pressure signals from the individual ones of the plurality of pressure sensors for a respective signal if it is determined that the computer did not receive the signal from the pressure sensor. The method further includes indicating an error if it is determined that no signal can be received from the remaining pressure sensors.

In a third example, where after opening the single valve, the method further includes measuring a rate of pressure rise in the process chamber by a rate of rise program and indicating a bad pressure sensor or marginal supply pressure if the single valve can be validated as open.

Program software code/instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some embodiments, the program software code/instructions associated with the flowcharts of various embodiments are executed by system 3000.

In some embodiments, the program software code/instructions associated with the flowcharts of various embodiments can be stored in a computer executable storage medium 503 and executed by processor 502. Here, computer executable storage medium 503 can be a tangible machine-readable medium that can be used to store program software code/instructions and data that, when executed by a computing device, causes one or more processors (e.g., processor 502) to perform a method(s) as may be recited in one or more accompanying claims directed to the disclosed subject matter.

The tangible machine readable medium 503 may include storage of the executable software program code/instructions and data in various tangible locations, including for example ROM, volatile RAM, non-volatile memory and/or cache and/or other tangible memory as referenced in the present application. Portions of this program software code/instructions and/or data may be stored in any one of these storage and memory devices. Further, the program software code/instructions can be obtained from other storage, including, e.g., through centralized servers or peer to peer networks and the like, including the Internet. Different portions of the software program code/instructions and data can be obtained at different times and in different communication sessions or in the same communication session.

The software program code/instructions associated with the various flowcharts and data can be obtained in their entirety prior to the execution of a respective software program or application by the computing device. Alternatively, portions of the software program code/instructions and data can be obtained dynamically, e.g., just in time, when needed for execution. Alternatively, some combination of these ways of obtaining the software program code/instructions and data may occur, e.g., for different applications, components, programs, objects, modules, routines or other sequences of instructions or organization of sequences of instructions, by way of example. Thus, it is not required that the data and instructions be on a tangible machine readable medium in entirety at a particular instance of time.

Examples of tangible computer-readable media 503 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions may be temporarily stored in digital tangible communication links while implementing electrical, optical, acoustical, or other forms of propagating signals, such as carrier waves, infrared signals, digital signals, etc. through such tangible communication links.

In general, tangible machine readable medium 503 may include any tangible mechanism that provides (i.e., stores and/or transmits in digital form, e.g., data packets) information in a form accessible by a machine (i.e., a computing device), which may be included, e.g., in a communication device, a computing device, a network device, a personal digital assistant, a manufacturing tool, a mobile communication device, whether or not able to download and run applications and subsidized applications from the communication network, such as the Internet, e.g., an iPhone®, Galaxy®, Blackberry® Android®, or the like, or any other device including a computing device. In one embodiment, processor-based system is in a form of or included within a PDA (personal digital assistant), a cellular phone, a notebook computer, a tablet, a game console, a set top box, an embedded system, a TV (television), a personal desktop computer, etc. Alternatively, the traditional communication applications and subsidized application(s) may be used in some embodiments of the disclosed subject matter.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

Example 1: An apparatus comprising: a plurality of valves in series, wherein individual ones of the plurality of valves comprise an inlet and an outlet, wherein an inlet of a first of the plurality of valves is connectable to a gas supply, and wherein an outlet of a last of the plurality of valves in the series is connectable to a process chamber; a plurality of pressure sensors; a pneumatic bank comprising a plurality of solenoid actuators, wherein individual ones of the plurality of solenoid actuators are mechanically coupled with individual ones of the plurality of valves, and wherein the individual ones of the plurality of pressure sensors are further coupled between a respective solenoid actuator in the plurality of solenoid actuators and a respective valve; and a communication interface coupled to the pneumatic bank and the plurality of pressure sensors, wherein the communication interface is configured to carry signals to and from the pneumatic bank and/or the plurality of pressure sensors to control and/or monitor status of an individual valve from the plurality of valves, wherein the communication interface is controllable by software.

Example 2: The apparatus of example 1, wherein the plurality of pressure sensors is coupled between a pneumatic gas outlet of the respective solenoid actuator and a pneumatic gas inlet of the respective valve.

Example 3: The apparatus of example 1, wherein the respective pressure sensor is configured to measure a relative change in a reference pneumatic gas pressure within a pneumatic gas line coupled between the pneumatic gas outlet of the respective solenoid actuator and a pneumatic gas inlet of the respective valve.

Example 4: The apparatus of example 1, wherein the plurality of pressure sensors are mounted on a housing, wherein the housing further comprises manifold connections between the plurality of solenoid actuators in the solenoid bank and the plurality of valves.

Example 5: The apparatus of example 4, wherein some of the plurality of pressure sensors are mounted on a top surface of the housing and other of the plurality of pressure sensors are mounted on a bottom surface of the housing.

Example 6: The apparatus of example 1, wherein a number of valves in the plurality of valves is at least two.

Example 7: The apparatus of example 1, wherein a number of valves in the plurality of valves is at least two but less than 20.

Example 8: The apparatus of example 4, wherein the housing is a first housing, wherein the communication interface is mounted on a second housing, the second housing coupled between the manifold connections of the first housing and the plurality of solenoid actuators.

Example 9: The apparatus of example 1, wherein the communication interface is to receive a signal from a computer to open or close a respective valve.

Example 10: The apparatus of example 1, wherein the communication interface is coupled to the pneumatic bank by a wireless connection.

Example 11: The apparatus of example 1, wherein the communication interface is coupled to the pneumatic bank by a wired connection.

Example 12: An apparatus comprising: a plurality of pressure sensors; a pneumatic bank comprising: a plurality of solenoid actuators; and a plurality of valves in series, wherein individual ones of the plurality of valves comprise an inlet and an outlet, wherein an inlet of a first of the plurality of valves is connectable to a gas supply, and wherein an outlet of a second of the plurality of valves in the series is connectable to a process chamber, wherein individual ones of the plurality of solenoid actuators are mechanically coupled with individual ones of the plurality of valves, and wherein the individual ones of the plurality of valves are further electrically coupled with individual ones of the plurality of pressure sensors; and a communication interface coupled to the pneumatic bank and the plurality of pressure sensors, wherein the communication interface is configured to carry signals to and from the pneumatic bank and/or the plurality of pressure sensors to control and/or monitor status of an individual valve from the plurality of valves.

Example 13: The apparatus of example 12, wherein the plurality of pressure sensors is coupled between a pneumatic gas outlet of the respective solenoid actuator and a pneumatic gas inlet of the respective valve.

Example 14: The apparatus of example 12, wherein the respective pressure sensor is configured to measure a relative change in a reference pneumatic gas pressure within a pneumatic gas line coupled between the pneumatic gas outlet of the respective solenoid actuator and a pneumatic gas inlet of the respective valve.

Example 15: The apparatus of example 12, wherein the plurality of pressure sensors are mounted on a housing, wherein the housing further comprises manifold connections between the plurality of solenoid actuators in the solenoid bank and the plurality of valves.

Example 16: The apparatus of example 15, wherein some of the plurality of pressure sensors are mounted on a top surface of the housing and other of the plurality of pressure sensors are mounted on a bottom surface of the housing.

Example 17: The apparatus of example 12, wherein a number of valves in the plurality of valves is at least two.

Example 18: The apparatus of example 12, wherein a number of valves in the plurality of valves is at least two but less than 20.

Example 19: The apparatus of example 15, wherein the housing is a first housing, wherein the communication interface is mounted on a second housing, the second housing coupled between the manifold connections of the first housing and the plurality of solenoid actuators.

Example 20: The apparatus of example 12, wherein the communication interface is to receive a signal from a computer to open or close a respective valve.

Example 21: The apparatus of example 12, wherein the communication interface is coupled to the pneumatic bank by a wireless connection.

Example 22: The apparatus of example 12, wherein the communication interface is coupled to the pneumatic bank by a wired connection.

Example 23: A method to verify a valve function, the method comprising: providing a gas to an inlet of a first valve from among a plurality of valves, wherein the plurality of valves are coupled in series, wherein an outlet of a second valve among the plurality of valves is connected with a process chamber, and wherein the plurality of valves are in a closed position; opening all but a single valve in the plurality of valves by actuating a respective solenoid actuator coupled with individual ones of the plurality of valves, wherein the respective solenoid actuator is among a plurality of solenoid actuators in a pneumatic bank; performing-a gas line pressure measurement at an outlet of the respective solenoid actuator coupled with the single valve to confirm a closed position of the single valve, wherein the measurement is performed by a respective pressure sensor coupled with the outlet of the respective solenoid actuator; and transmitting a signal to a computer coupled with the pressure sensor, the signal comprising the gas line pressure measurement.

Example 24: The method of example 23, wherein prior to providing gas, the method further comprises pumping the process chamber to a reference pressure and transmitting the reference pressure reading to a computer.

Example 25: The method of example 24, wherein after transmitting the signal comprising the gas line pressure measurement, the method further comprises: opening the single valve by energizing the respective solenoid actuator coupled to the single valve, the opening causing the gas to flow to the process chamber; and measuring the gas line pressure at the outlet of the respective solenoid actuator coupled with the single valve to confirm an open position of the single valve.

Example 26: The method of example 25 further comprising measuring a rate of pressure rise in the process chamber by a vacuum gauge coupled with the process chamber.

Example 27: The method of example 26, further comprising comparing the rate of pressure rise with the reference pressure by the computer to validate opening of the single valve.

Example 28: The method of example 27, further comprising sending a notification to the computer, the notification indicative of opening of the single valve to change the reference pressure.

Example 29: The method of example 27, wherein if no change in the reference pressure is measured, the method further comprises performing a manual check of air line connections between the respective solenoid actuator and the respective single valve.

Example 30: A system comprising: a gas supply; a process chamber comprising: a chamber pressure measurement gauge; and a throttle valve coupled between a vacuum pump and the process chamber; a plurality of valves in series, wherein individual ones of the plurality of valves comprise an inlet and an outlet, wherein an inlet of a first of the plurality of valves is connected to the gas supply, and wherein an outlet of a last of the plurality of valves in the series is connected to the process chamber; a plurality of pressure sensors; a pneumatic bank comprising a plurality of solenoid actuators, wherein individual ones of the plurality of solenoid actuators are mechanically coupled with individual ones of the plurality of valves, and wherein the individual ones of the plurality of plurality of pressure sensors are further coupled between a respective solenoid actuator in the plurality of solenoid actuators and the respective valve; a communication interface coupled to the pneumatic bank and the plurality of pressure sensors, wherein the communication interface is configured to carry signals to and from the pneumatic bank and/or the plurality of pressure sensors to control and/or monitor status of an individual valve from the plurality of valves, and wherein the communication interface is controllable by software; and a computer to send and/or receive signal from the communication interface.

Example 31: The system of example 30, wherein the plurality of pressure sensors is coupled between a pneumatic gas outlet of the respective solenoid actuator and a pneumatic gas inlet of the respective valve.

Example 32: The system of example 30, wherein the respective pressure sensor is configured to measure a relative change in a reference pneumatic gas pressure within a pneumatic gas line coupled between the pneumatic gas outlet of the respective solenoid actuator and a pneumatic gas inlet of the respective valve.

Example 33: The system of example 30, wherein the plurality of pressure sensors is mounted on a housing, wherein the housing further comprises manifold connections between the plurality of solenoid actuators in the solenoid bank and the plurality of valves.

Example 34: The system of example 33, wherein some of the plurality of pressure sensors are mounted on a top surface of the housing and other of the plurality of pressure sensors are mounted on a bottom surface of the housing.

Example 35: The system of example 30, wherein a number of valves in the plurality of valves is at least two.

Example 36: The system of example 30, wherein a number of valves in the plurality of valves is at least two but less than 20.

Example 37: The system of example 33, wherein the housing is a first housing, wherein the communication interface is mounted on a second housing, the second housing coupled between the manifold connections of the first housing and the plurality of solenoid actuators.

Example 38: The system of example 30, wherein the communication interface is to receive a signal from a computer to open or close a respective valve.

Example 39: The system of example 30, wherein the communication interface is coupled to the pneumatic bank by a wireless connection.

Example 40: The system of example 30, wherein the communication interface is coupled to the pneumatic bank by a wired connection.

Example 41: A machine-readable storage media having machine-readable instructions, that when executed, cause one or more machines to perform a method comprising: providing a gas to an inlet of a first valve from among a plurality of valves, wherein the plurality of valves are coupled in series, wherein an outlet of a second valve among the plurality of valves is connected with a process chamber, and wherein the plurality of valves are in a closed position; opening all but a single valve in the plurality of valves by actuating a respective solenoid actuator coupled with individual ones of the plurality of valves, wherein the respective solenoid actuator is among a plurality of solenoid actuators in a pneumatic bank; pumping the process chamber to a reference pressure; and opening the single valve by energizing the respective solenoid actuator coupled to the single valve, the opening causing the gas to flow to the process chamber.

Example 42: The machine-readable storage media of example 41 having further machine-readable instructions, that when executed, cause the one or more machines to perform a further method comprising determining whether the one or more machines received a signal from a pressure sensor; and indicating that the respective solenoid actuator is activated if it is determined that signal is received from the pressure sensor.

Example 43: The machine-readable storage media of example 41 having further machine-readable instructions, that when executed, cause the one or more machines to perform a further method comprising: checking remaining pressure signals from a plurality of pressure sensors for a signal if it is determined that a computer did not receive the signal from the pressure sensor; and indicating an error if it is determined that no signal is received from the remaining pressure sensors.

Example 44: The machine-readable storage media of example 41, wherein after opening the single valve, the method further comprising: measuring a rate of pressure rise in the process chamber by a rate of rise program; and indicating a bad pressure sensor or marginal supply pressure if the single valve is validated as open.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus comprising:
a plurality of valves in series, wherein individual ones of the plurality of valves comprise an inlet and an outlet, wherein an inlet of a first of the plurality of valves is connectable to a gas supply, and wherein an outlet of a last of the plurality of valves in the series is connectable to a process chamber;
a plurality of pressure sensors;
a pneumatic bank comprising a plurality of solenoid actuators, wherein individual ones of the plurality of solenoid actuators are mechanically coupled with individual ones of the plurality of valves, and wherein the individual ones of the plurality of pressure sensors are further coupled between a respective solenoid actuator in the plurality of solenoid actuators and a respective valve; and
a communication interface coupled to the pneumatic bank and the plurality of pressure sensors, wherein the communication interface is configured to carry signals to and from the pneumatic bank and/or the plurality of pressure sensors to control and/or monitor status of an individual valve from the plurality of valves, wherein the communication interface is controllable by software.

2. The apparatus of claim 1, wherein the plurality of pressure sensors is coupled between a pneumatic gas outlet of the respective solenoid actuator and a pneumatic gas inlet of the respective valve.

3. The apparatus of claim 1, wherein the respective pressure sensor is configured to measure a relative change in a reference pneumatic gas pressure within a pneumatic gas line coupled between the pneumatic gas outlet of the respective solenoid actuator and a pneumatic gas inlet of the respective valve.

4. The apparatus of claim 1, wherein the plurality of pressure sensors is mounted on a housing, wherein the housing further comprises manifold connections between the plurality of solenoid actuators in the solenoid bank and the plurality of valves.

5. The apparatus of claim 4, wherein some of the plurality of pressure sensors are mounted on a top surface of the housing and other of the plurality of pressure sensors are mounted on a bottom surface of the housing.

6. The apparatus of claim 1, wherein a number of valves in the plurality of valves is at least two.

7. The apparatus of claim 1, wherein a number of valves in the plurality of valves is at least two but less than 20.

8. The apparatus of claim 4, wherein the housing is a first housing, wherein the communication interface is mounted on a second housing, the second housing coupled between the manifold connections of the first housing and the plurality of solenoid actuators.

9. The apparatus of claim 1, wherein the communication interface is to receive a signal from a computer to open or close a respective valve.

10. The apparatus of claim 1, wherein the communication interface is coupled to the pneumatic bank by a wireless connection.

11. The apparatus of claim 1, wherein the communication interface is coupled to the pneumatic bank by a wired connection.

12. An apparatus comprising:
a plurality of pressure sensors;
a pneumatic bank comprising:
a plurality of solenoid actuators; and
a plurality of valves in series, wherein individual ones of the plurality of valves comprise an inlet and an outlet, wherein an inlet of a first of the plurality of valves is connectable to a gas supply, and wherein an outlet of a second of the plurality of valves in the series is connectable to a process chamber, wherein individual ones of the plurality of solenoid actuators are mechanically coupled with individual ones of the plurality of valves, and wherein the individual ones of the plurality of valves are further electrically coupled with individual ones of the plurality of pressure sensors; and
a communication interface coupled to the pneumatic bank and the plurality of pressure sensors, wherein the communication interface is configured to carry signals to and from the pneumatic bank and/or the plurality of pressure sensors to control and/or monitor status of an individual valve from the plurality of valves.

13. The apparatus of claim 12, wherein the plurality of pressure sensors is coupled between a pneumatic gas outlet of the respective solenoid actuator and a pneumatic gas inlet of the respective valve.

14. The apparatus of claim 12, wherein the respective pressure sensor is configured to measure a relative change in a reference pneumatic gas pressure within a pneumatic gas line coupled between the pneumatic gas outlet of the respective solenoid actuator and a pneumatic gas inlet of the respective valve.

15. The apparatus of claim 12, wherein the plurality of pressure sensors is mounted on a housing, wherein the housing further comprises manifold connections between the plurality of solenoid actuators in the solenoid bank and the plurality of valves.

16. The apparatus of claim 15, wherein some of the plurality of pressure sensors are mounted on a top surface of the housing and other of the plurality of pressure sensors are mounted on a bottom surface of the housing.

17. The apparatus of claim 12, wherein a number of valves in the plurality of valves is at least two.

18. The apparatus of claim 12, wherein a number of valves in the plurality of valves is at least two but less than 20.

19. The apparatus of claim 15, wherein the housing is a first housing, wherein the communication interface is mounted on a second housing, the second housing coupled between the manifold connections of the first housing and the plurality of solenoid actuators.

20. The apparatus of claim 12, wherein the communication interface is to receive a signal from a computer to open or close a respective valve.

21. The apparatus of claim 12, wherein the communication interface is coupled to the pneumatic bank by a wireless connection.

22. The apparatus of claim 12, wherein the communication interface is coupled to the pneumatic bank by a wired connection.

23. A method to verify a valve function, the method comprising:
providing a gas to an inlet of a first valve from among a plurality of valves, wherein the plurality of valves is coupled in series, wherein an outlet of a second valve among the plurality of valves is connected with a process chamber, and wherein the plurality of valves is in a closed position;
opening all but a single valve in the plurality of valves by actuating a respective solenoid actuator coupled with individual ones of the plurality of valves, wherein the respective solenoid actuator is among a plurality of solenoid actuators in a pneumatic bank;
performing a gas line pressure measurement at an outlet of the respective solenoid actuator coupled with the single valve to confirm a closed position of the single valve, wherein the measurement is performed by a respective pressure sensor coupled with the outlet of the respective solenoid actuator; and
transmitting a signal to a computer coupled with the pressure sensor, the signal comprising the gas line pressure measurement.

24. The method of claim 23, wherein prior to providing gas, the method further comprises pumping the process chamber to a reference pressure and transmitting the reference pressure reading to a computer.

25. The method of claim 24, wherein after transmitting the signal comprising the gas line pressure measurement, the method further comprises:
opening the single valve by energizing the respective solenoid actuator coupled to the single valve, the opening causing the gas to flow to the process chamber; and
measuring the gas line pressure at the outlet of the respective solenoid actuator coupled with the single valve to confirm an open position of the single valve.
